(19) United States
(12) Patent Application Publication
(10) Pub. No.: US 2008/0099919 A1
(43) Pub. Date: May 1, 2008

(54) SEMICONDUCTOR DEVICE INCLUDING COPPER INTERCONNECT AND METHOD FOR MANUFACTURING THE SAME

(75) Inventor: Koichi Ozawa, Kyoto (JP)

Correspondence Address: CANTOR COLBURN, LLP, 20 Church Street, 22nd Floor, Hartford, CT, 06103, US

(73) Assignee: ROHM CO., LTD., Kyoto-fu (JP)

(21) Appl. No.: 11/865,219

(22) Filed: Oct. 1, 2007

(30) Foreign Application Priority Data
Sep. 29, 2006 (JP) JP2006-268309

(51) Int. Cl. H01L 21/4763; H01L 23/52

(52) U.S. Cl. 257/751; 438/653; 257/E23.141; 257/E21.495

(57) ABSTRACT

Semiconductor device includes a semiconductor element, a copper interconnect electrically connected to the semiconductor element, a barrier layer containing metal capable of suppressing diffusion and oxidation of copper and continuously covers top and side surfaces of the copper interconnect, and an adhesive layer formed on a top surface of the barrier layer.

### CROSS REFERENCE TO RELATED APPLICATOIN AND INCORPORATION BY REFERENCE

This application is based upon and claims the benefit of priority from prior Japanese Patent Application P2006-268309 filed on Sep. 29, 2006; the entire contents of which are incorporated by reference herein.

### BACKGROUND OF THE INVENTION

1. Field of the Invention

The present invention relates to a semiconductor device including copper interconnect and a method of manufacturing the same.

2. Description of the Related Art

There have hitherto been known semiconductor devices which include copper interconnects capable of providing low resistance and methods for manufacturing such semiconductor devices. One of such semiconductor devices is, for example, a semiconductor device shown in FIG. 1. The semiconductor device 101 shown in FIG. 1 includes a copper interconnect 103 formed on a substrate 102 and a protection film 104 covering side surfaces of the copper interconnect 103. The protection film 104 is composed of resin such as insulating polyimide and protects the copper interconnect from physical damages and the like while suppressing diffusion and oxidation of copper.

Since the protection film 104 is insulating, a conductive barrier layer 105 and a conductive adhesive layer 106 formed on the conductive barrier layer 105 are provided on the top surface of the copper interconnect 103 to electrically connect a wire (not shown) and the copper interconnect 103. The barrier layer 105, which contains metal capable of suppressing diffusion of copper, suppresses diffusion of copper into the adhesive layer 106 and accordingly suppresses reduction in adhesion of the adhesive layer 106 to the wire.

The Japanese Patent Laid-open Publication No. 2001-319946 describes a semiconductor device including: a copper interconnect formed by the damascene process; a first barrier layer covering bottom and side surfaces of the copper interconnect; and a second barrier layer covering a part of the top surface of the copper interconnect. In this semiconductor device, by covering the side surfaces of the copper interconnect with the second barrier layer, lateral diffusion of copper can be suppressed to some extent.

However, in the case of the semiconductor device 101 shown in FIG. 1, since the side surfaces of the copper interconnect are covered with the protection film 104, a process to form and pattern the protection film 104 is required in addition to a process to form the barrier layer 105, thus causing a problem with a complicated manufacturing process. Moreover, there is another problem that the diffusion of copper cannot be sufficiently suppressed by the protection film 104, which is made of resin.

In the semiconductor device of the Japanese Patent Laid-open Publication No. 2001-319946, on the other hand, since the second barrier layer covers only a part of the top surface of the copper interconnect, the diffusion of copper into the adhesive layer cannot be sufficiently suppressed. Even if the second barrier layer is formed so as to cover the entire top surface of the copper interconnect, the first and second barrier layers are discontinuously formed, between which a gap can be easily created by expansion or contraction. As a result, even if the second barrier layer is formed so as to cover the entire top surface of the copper interconnect, lateral diffusion of copper cannot be sufficiently suppressed.

### SUMMARY OF THE INVENTION

The present invention was invented to solve the aforementioned problems, and an object of the present invention is to provide a semiconductor device with diffusion of copper further suppressed and with a manufacturing process simplified and a method for manufacturing the semiconductor device.

A semiconductor device according to a first aspect of the present invention includes a semiconductor element, a copper interconnect electrically connected to the semiconductor element, a barrier layer containing metal capable of suppressing diffusion and oxidation of copper and continuously covers top and side surfaces of the copper interconnect, and an adhesive layer formed on a top surface of the barrier layer.

Preferably, the barrier layer is composed of one of TaN, Ni, Co, Cr, Mo, Ti, and W.

More preferably, the semiconductor device according to the first aspect of the present invention further includes a lower barrier layer which contains metal capable of suppressing diffusion and oxidation of copper and is formed on a bottom surface of the copper interconnect.

Still more preferably, the lower barrier layer is composed of one of TiW, Ti, and TiN.

A method for manufacturing a semiconductor device according to a second aspect of the present invention includes: forming a semiconductor element, forming a copper interconnect electrically connected to the semiconductor element using a resist film, removing the resist film, forming a barrier layer which contains metal capable of diffusion and oxidation of copper and continuously covers top and side surfaces of the copper interconnect, and forming an adhesive layer on a top surface of the barrier layer.

Preferably, the barrier layer is formed by chemical vapor deposition (CVD).

More preferably, the barrier layer is composed of one of TaN, Ni, Co, Cr, Mo, Ti, and W.

Still more preferably, the method for manufacturing a semiconductor device according to the second aspect of the present invention further includes: forming a lower barrier layer on a bottom surface of the copper interconnect, the lower barrier layer containing metal capable of suppressing diffusion and oxidation of copper.

Still more preferably, after the resist film is removed, the lower barrier layer is formed by removing a part of the lower barrier layer which is exposed from the copper interconnect.

Still more preferably, the lower barrier layer is composed of one of TiW, Ti, and TiN.

According to the semiconductor device of the present invention, the top and side surfaces of the copper interconnect are covered with the continuous barrier layer composed of metal capable of suppressing diffusion and oxidation of copper. Compared to the case where the side surfaces of the copper interconnect are covered with a protection film made of resin, therefore, it is possible to further suppress diffusion of copper while facilitating the manufacturing process by omitting the step of forming the protection film.

Moreover, the entire top surface of the copper interconnect can be covered by forming the continuous barrier layer on the top and side surfaces of the copper interconnect. It is therefore possible to further suppress upward diffusion of copper and accordingly suppress reduction in adhesion of the adhesive layer to a wire. Furthermore, there is no gap created by expansion or contraction due to heat between the barrier layers unlike the case where the top and side surfaces of the copper interconnect are covered with different barrier layers. It is therefore possible to suppress exposure of the copper interconnect and accordingly further suppress lateral diffusion of copper.

A semiconductor device manufactured by the method for manufacturing a semiconductor device of the present invention has same effects as those of the aforementioned semiconductor device.

### BRIEF DESCRIPTION OF DRAWINGS

FIG. 1 is a cross-sectional view of a conventional semiconductor device.

FIG. 2 is a cross-sectional view of a semiconductor device according to an embodiment of the present invention.

FIG. 3 is a cross-sectional view of the semiconductor device in a step of a manufacturing process.

FIG. 4 is a cross-sectional view of the semiconductor device in a step of the manufacturing process.

FIG. 5 is a cross-sectional view of the semiconductor device in a step of the manufacturing process.

FIG. 6 is a cross-sectional view of the semiconductor device in a step of the manufacturing process.

FIG. 7 is a cross-sectional view of the semiconductor device in a step of the manufacturing process.

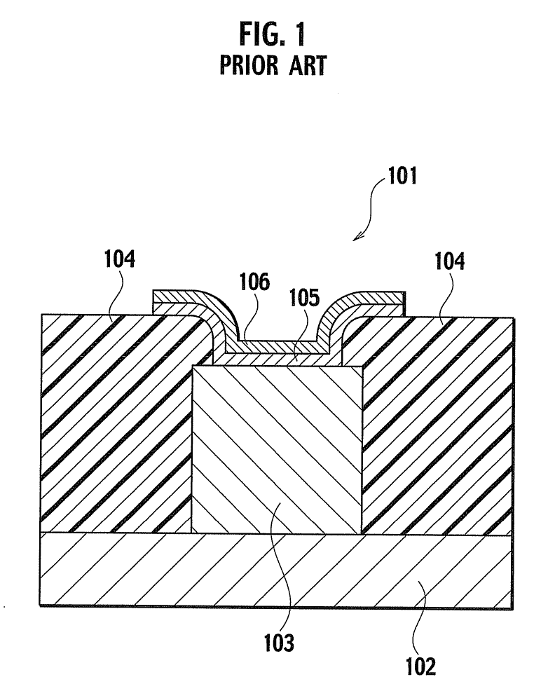

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### Embodiment

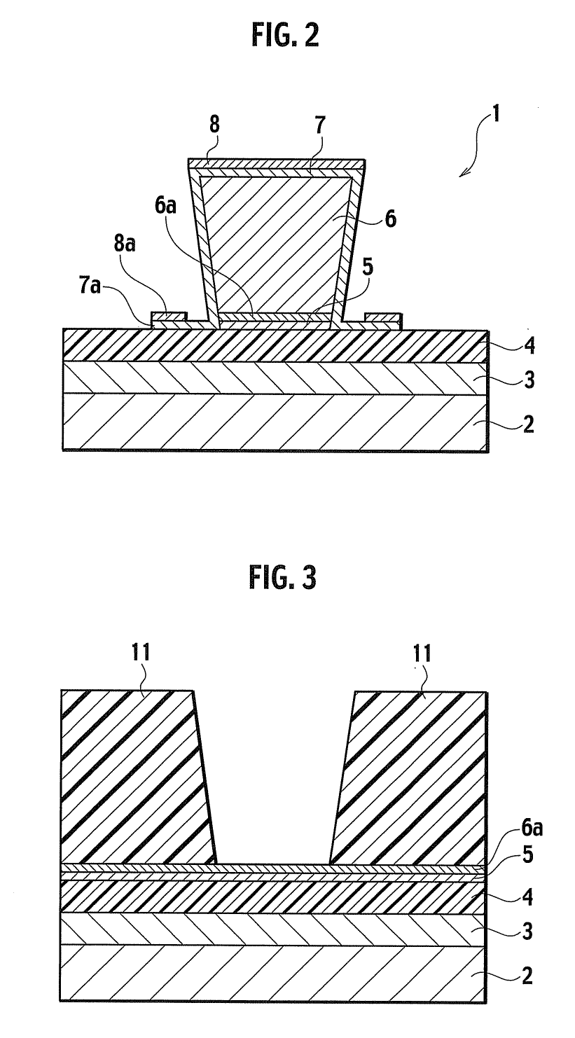

Hereinafter, with reference to the drawings, a description is given of an embodiment in which the present invention is applied to an LSI. FIG. 2 is a cross-sectional view of a semiconductor device according to the embodiment of the present invention.

As shown in FIG. 2, a semiconductor device 1 includes a semiconductor element layer 2, an interconnect layer 3, a polyimide layer 4, a first barrier layer 5, a copper interconnect 6, a second barrier layer (corresponding to a barrier layer described in claims) 7, and an adhesive layer 8.

The semiconductor element layer 2 includes a plurality of semiconductor elements (not shown) such as diodes and transistors.

The interconnect layer 3 includes aluminum interconnects of a multilayer structure for electrically connecting the plurality of semiconductor elements, an interlayer insulation film for insulating aluminum interconnects in different layers from each other, and plugs for connecting aluminum interconnects in different layers (not shown). The aluminum interconnects may be composed of just aluminum metal or composed of an aluminum alloy such as AlCu and AlSiCu.

In the polyimide layer 4, through-holes (not shown) are formed to electrically connect an aluminum interconnect of the interconnect layer 3 to the copper interconnect 6 with the first barrier layer 5 interposed therebetween.

The first barrier layer 5 electrically connects the aluminum interconnect formed in the interconnect layer 3 and the copper interconnect 6 while suppressing diffusion of copper into the underlying layers including the semiconductor element layer 2. The first barrier layer 5 is composed of TiW, which is conductive and is capable of suppressing diffusion and oxidation of copper, and is formed so as to cover the bottom surface of the copper interconnect 6. The first barrier layer 5 may be composed of Ti, TiN, or the like.

The copper interconnect 6 has such a thickness that low resistance can be obtained (for example, about 5 μm to 20 μm). The copper interconnect 6 is electrically connected to the semiconductor elements formed in the semiconductor layer 2 to electrically connect the semiconductor elements to each other. The copper interconnect 6 is formed above the interconnect layer 3, or formed in the topmost layer among the interconnect layers, and electrically connected to a wire (not shown) with the adhesive layer 8 and second barrier layer 7 interposed therebetween. The copper interconnect 6 includes a copper seed layer 6a formed in a later-described manufacturing process.

The second barrier 7 electrically connects the copper interconnect 6 and the wire while suppressing the diffusion of copper into the adhesive layer 8 above and in the horizontal direction. The second barrier layer 7 is composed of TaN, which is conductive and is capable of suppressing diffusion and oxidation of copper, and is continuously formed so as to cover the top and side surfaces of the copper interconnect 6.

Herein, the material constituting the second barrier layer 7 is not limited to TaN and can be metal such as Ni, Co, Cr, Mo, Ti , and W or an alloy or a nitride containing such metal. A second barrier layer 7a, which is formed on the polyimide layer 4, is formed for manufacturing reasons and does not have a special function.

The adhesive layer 8 electrically connects the copper interconnect 6 and the wire while increasing the adhesion to the wire instead of the copper interconnect 6, which has low adhesion to the wire composed of Au. The adhesive layer 8 is composed of Al, which is conductive and has high adhesion to the wire, so as to cover the top surface of the second barrier layer 7.

Herein, the material constituting the adhesive layer 8 is not limited to Al but may be AlCu, AlSiCu, or the like. The adhesive layer 8a, which is formed on the second barrier layer 7a, is formed for manufacturing reasons and does not have a special function.

Next, a description is given of a method for manufacturing the aforementioned semiconductor device with reference to FIGS. 3 to 7. FIGS. 3 to 7 are cross sectional views of the semiconductor device in individual steps of a manufacturing process.

First, as shown in FIG. 3, the semiconductor element layer 2 containing semiconductor elements, the interconnect layer 3 containing aluminum interconnects, and the polyimide layer 4 are sequentially formed. The first barrier layer 5 composed of TiW is then formed on the entire top surface of the polyimide layer 4 by sputtering, and the copper seed layer 6a is formed on the entire top surface of the first barrier layer 5 by sputtering. Thereafter, a resist film 11 is formed by photolithography in a region other than a region where the copper interconnect 6 is formed. Herein, since light hardly reaches under the resist film 11 in exposure to light, the resist film 11 is formed so that opening width in the bottom surface is smaller than that in the top surface.

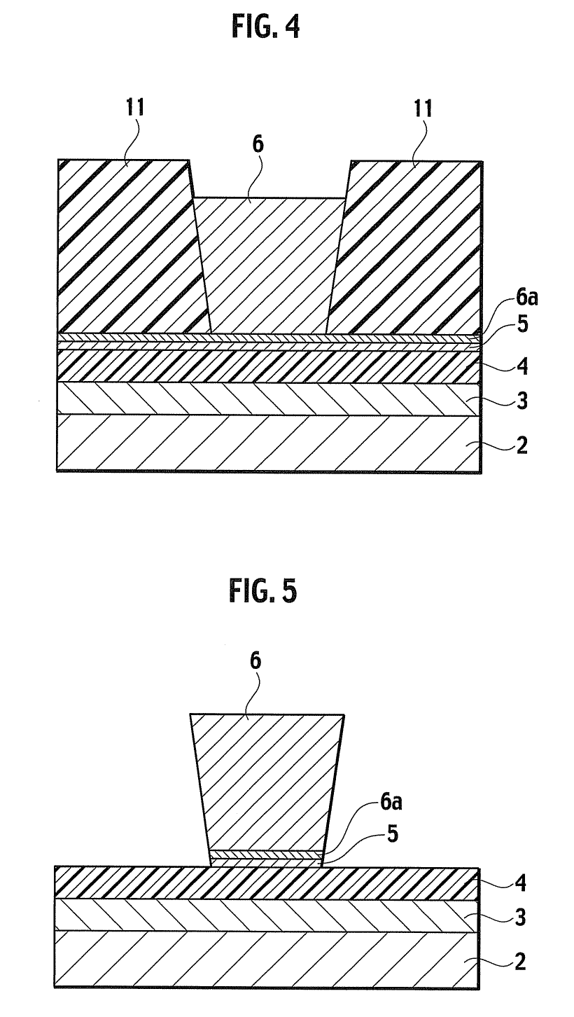

Next, as shown in FIG. 4, the copper interconnect 6 is formed by electrolytic plating on a part of the copper seed layer 6a exposed from the resist film 11.

Next, as shown in FIG. 5, the resist film 11 is removed. A part of the copper seed layer 6a which is exposed by the removal of the resist film 11 is then removed by etching. Subsequently, a part of the first barrier layer 5 which is exposed by the removal of the copper seed layer 6a is removed by etching so that only a part of the first barrier layer 5 underlying the copper interconnect 6 remains. Thereafter, an oxidized film in the surface of the copper interconnect 6 is removed by etching.

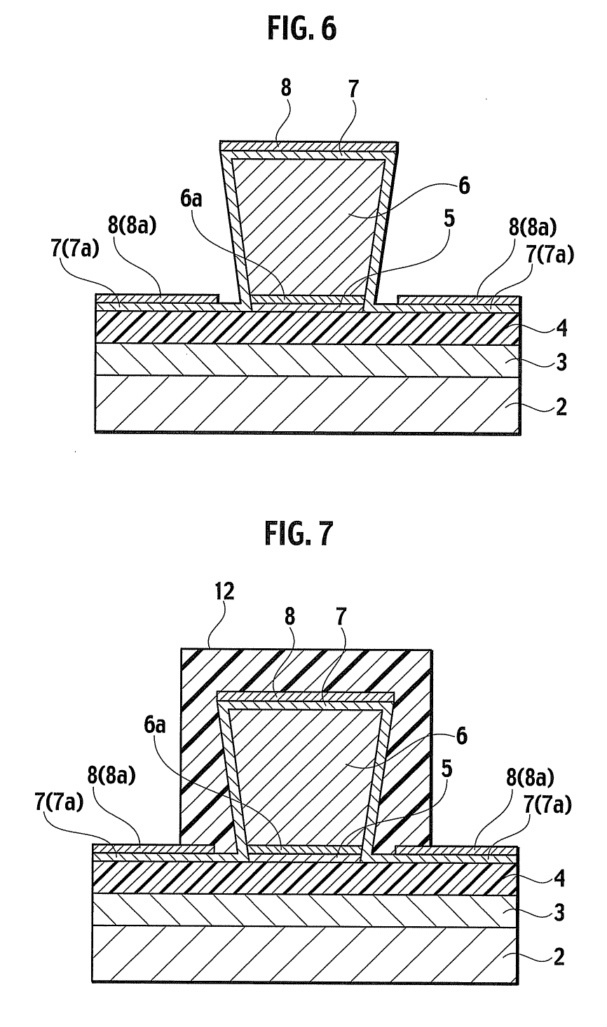

Next, as shown in FIG. 6, the second barrier layer 7, which is composed of TaN, is formed by plasma CVD so as to cover the top and side surfaces of the copper interconnect 6 and the top surface of the polyimide layer 4. The adhesive layer 8, which is composed of Al, is then formed by sputtering so as to cover the top surface of the second barrier layer 7. Herein, since the adhesive layer 8 is formed by sputtering, the adhesive layer 8 is not formed in a region which is hidden by the adhesive layer 7 when viewed from above.

Next, as shown in FIG. 7, a resist film 12 is formed by photolithography so as to cover the copper interconnect 6 and a part of the second barrier layer 7 and a part of the adhesive layer 8 in the periphery of the copper interconnect 6.

Next, as shown in FIG. 2, a part of the adhesive layer 8 which is exposed from the resist film 12 is removed so that a part of the adhesive layer 8 which is located over the copper interconnect remains. A part of the second barrier layer 7 which is exposed by the removal of the adhesive layer 8 is then removed so that a part of the second barrier layer 7 on the top and side surfaces of the copper interconnect 6 remains. Thereafter, the resist film 12 is removed. Eventually, a wire is bonded to a desired region of the adhesive layer 8, and then the whole of the obtained device is covered with mold resin (not shown), thus completing the semiconductor device 1.

In the semiconductor device 1 as described above, the top and side surfaces of the copper interconnect 6 are covered with the continuous second barrier layer 7 composed of TaN, which is capable of suppressing diffusion and oxidation of copper. Accordingly, compared to the case where side surfaces of the copper interconnect 6 are covered with a protection film made of resin, it is possible to further suppress diffusion of copper while facilitating the manufacturing process by omitting the step of forming the protection film.

The entire top surface of the copper interconnect 6 can be covered by forming the second barrier layer 7 continuously on the top and side surfaces of the copper interconnect 6. It is therefore possible to further suppress upward diffusion of copper and accordingly suppress reduction in adhesion of the adhesive layer 8 to the wire.

Furthermore, there is no gap created by expansion or contraction due to heat between the barrier layers unlike the case where the top and side surfaces of the copper interconnect are covered with different barrier layers. It is therefore possible to suppress exposure of the copper interconnect 6 and accordingly further suppress lateral diffusion of copper.

Moreover, the second barrier layer 7 is formed by plasma CVD. It is therefore possible to easily form the second barrier layer 7 on the upper and side surfaces of the copper interconnect 6.

Hereinabove, the present invention is described using the embodiment but is not limited to the embodiment described in the specification. The scope of the present invention is determined by the claims and the scope equivalent to the scope of the clams. A description is given of modifications of the aforementioned embodiment with some parts modified.

For example, each of the materials constituting the aforementioned semiconductor device 1 is just an example and can be properly changed.

Moreover, the above description shows an example in which the present invention is applied to an LSI, but the present invention can be applied to other semiconductor devices such as discrete semiconductors.

In the aforementioned embodiment, the second barrier layer 7 is formed by plasma CVD but may be formed by another method such as plating.

Various modifications will become possible for those skilled in the art after receiving the teachings of the present disclosure without departing from the scope thereof.

What is claimed is:

1. A semiconductor device comprising:
a semiconductor element;
a copper interconnect electrically connected to the semiconductor element;
a barrier layer containing metal capable of suppressing diffusion and oxidation of copper and continuously covers top and side surfaces of the copper interconnect; and
an adhesive layer formed on a top surface of the barrier layer.

2. The semiconductor device of claim 1, wherein:
the barrier layer is composed of one of TaN, Ni, Co, Cr, Mo, Ti, and W.

3. The semiconductor device of claim 1, further comprising:
a lower barrier layer which contains metal capable of suppressing diffusion and oxidation of copper and is formed on a bottom surface of the copper interconnect.

4. The semiconductor device of claim 3, wherein:
the lower barrier layer is composed of one of TiW, Ti, and TiN.

5. A method for manufacturing a semiconductor device, the method comprising:
forming a semiconductor element;
forming a copper interconnect electrically connected to the semiconductor element using a resist film;
removing the resist film;
forming a barrier layer which contains metal capable of diffusion and oxidation of copper and continuously covers top and side surfaces of the copper interconnect; and
forming an adhesive layer on a top surface of the barrier layer.

6. The method of claim 5, wherein:
the barrier layer is formed by chemical vapor deposition (CVD).

7. The method of claim 5, wherein:
the barrier layer is composed of one of TaN, Ni, Co, Cr, Mo, Ti, and W.

8. The method of claim 5, further comprising:
forming a lower barrier layer on a bottom surface of the copper interconnect, the lower barrier layer containing metal capable of suppressing diffusion and oxidation of copper.

9. The method of claim 8, wherein:
after the resist film is removed, the lower barrier layer is formed by removing a part of the lower barrier layer which is exposed from the copper interconnect.

10. The method of claim 8, wherein:
the lower barrier layer is composed of one of TiW, Ti, and TiN.
